(19) United States
(12) Patent Application Publication
(10) Pub. No.: US 2014/0191319 A1
(43) Pub. Date: Jul. 10, 2014

(54) FINFET COMPATIBLE DIODE FOR ESD PROTECTION

(71) Applicants: INTERNATIONAL BUSINESS MACHINES CORPORATION, Armonk, NY (US); GLOBALFOUNDRIES, INC., Grand Cayman Islands (KY)

(72) Inventors: Kangguo Cheng, Schenectady, NY (US); Shom Ponoth, Clifton Park, NY (US); Balasubramanian Pranatharthiharan, Watervliet, NY (US); Theodorus Eduardus Standaert, Clifton Park, NY (US); Tenko Yamashita, Schenectady, NY (US); Robert J. Miller, Yorktown Heights, NY (US)

(73) Assignees: GLOBALFOUNDRIES, INC., Grand Cayman Islands (KY); INTERNATIONAL BUSINESS MACHINES CORPORATION, Armonk, NY (US)

(21) Appl. No.: 13/733,943

(22) Filed: Jan. 4, 2013

(51) Int. Cl. H01L 29/78; H01L 21/02

(52) U.S. Cl. CPC H01L 29/785; H01L 29/78; H01L 21/02381
USPC 257/347; 257/355; 438/479

(57) ABSTRACT

A diode for integration with finFET devices is disclosed. An in-situ doped epitaxial silicon region is grown on the cathode or anode of the diode to increase the surface area of the junction and overall silicon volume for improved heat dissipation during an ESD event.

### FIELD OF THE INVENTION

The present invention relates generally to semiconductor fabrication, and more particularly, to diode and method of fabrication.

### BACKGROUND OF THE INVENTION

Extremely high voltages can develop in the vicinity of an integrated circuit due to the build-up of static charges. A high potential may be generated to an input or output buffer of the integrated circuit, which may be caused, for example, by a person touching a package pin that is in electrical contact with the input or output buffer. When the electrostatic charges are discharged, a high current is produced at the package nodes of the integrated circuit, and is referred to as electrostatic discharge (ESD).

ESD is becoming a serious problem for semiconductor devices as the demand for higher operating speed, smaller operating voltages, higher packing density and reduced cost drives a reduction of all device dimensions. This generally implies thinner dielectric layers, higher doping levels with more abrupt doping transitions, and higher electric fields—all factors that contribute to an increased sensitivity to damaging ESD events.

FinFET technology is becoming more prevalent as device size continues to shrink. It is therefore desirable to have an improved structure and fabrication process for forming ESD-tolerant devices that are compatible with the formation of FinFET structures.

### SUMMARY OF THE INVENTION

In one embodiment, a semiconductor diode is provided. The diode comprises an N− region, an L-shaped P− region formed within the N− region, wherein the L-shaped P− region forms an L-shaped junction with the N− region, and a P+ region disposed above and alongside the P− region.

In another embodiment, a semiconductor structure is provided. The structure comprises a first silicon region, an insulator region disposed over the first silicon region, a diode, the diode comprising a second silicon region disposed over the insulator region, an N+ region formed in the second silicon region, an N− region formed in the second silicon region and disposed adjacent to the N+ region, an L-shaped P− region formed within the N− region, wherein the L-shaped P− region forms an L-shaped junction with the N− region, and a P+ region disposed above and alongside the P− region. There is a finFET adjacent to the diode.

In another embodiment, a method of forming a diode is provided. The method comprises forming a silicon-on-insulator region, forming a polysilicon region on the silicon-on-insulator region, depositing a nitride layer over the silicon-on-insulator region, forming an N+ region in the silicon-on-insulator region, removing a portion of the nitride layer to form an exposed portion of the silicon-on-insulator region, forming an in-situ P-doped epitaxial layer on the exposed portion of the silicon-on-insulator region, performing an activation anneal, and forming a first contact over the N+ region and a second contact over the in-situ P-doped epitaxial layer.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG). Furthermore, for clarity, some reference numbers may be omitted in certain drawings.

FIG. 1 shows a semiconductor structure at a starting point for a method in accordance with an embodiment of the present invention.

FIG. 2 shows a semiconductor structure after subsequent processing steps of forming multiple fins from an SOI region.

FIG. 3 shows a semiconductor structure after subsequent processing steps of depositing a resist region and performing a well implant.

FIG. 4 shows a semiconductor structure after subsequent processing steps of depositing polysilicon and an oxide layer.

FIG. 5 shows a semiconductor structure after a subsequent processing step of depositing a nitride layer.

FIG. 6 shows a semiconductor structure after a subsequent processing step of depositing another resist region.

FIG. 7 shows a semiconductor structure after a subsequent processing step of removing a portion of the nitride layer.

FIG. 8 shows a semiconductor structure after a subsequent processing step of forming a P+ epitaxial layer.

FIG. 9 shows a semiconductor structure after subsequent processing steps of depositing another resist region and forming an N+ region.

FIG. 10 shows a semiconductor structure after subsequent processing steps of removing the resist region and performing an activation anneal.

FIG. 10A shows details of the semiconductor structure of FIG. 10.

FIG. 11 shows a semiconductor structure after a subsequent processing step of adding electrical contacts.

FIG. 12 is a flowchart indicating process steps for an embodiment of the present invention.

### DETAILED DESCRIPTION

Integrating diodes with finFETs has various challenges, including forming sufficient junction area as to be resilient to ESD events. Embodiments of the present invention grow an in-situ doped epitaxial silicon region on the cathode or anode of the diode to increase the surface area of the junction and overall silicon volume for improved heat dissipation during an ESD event.

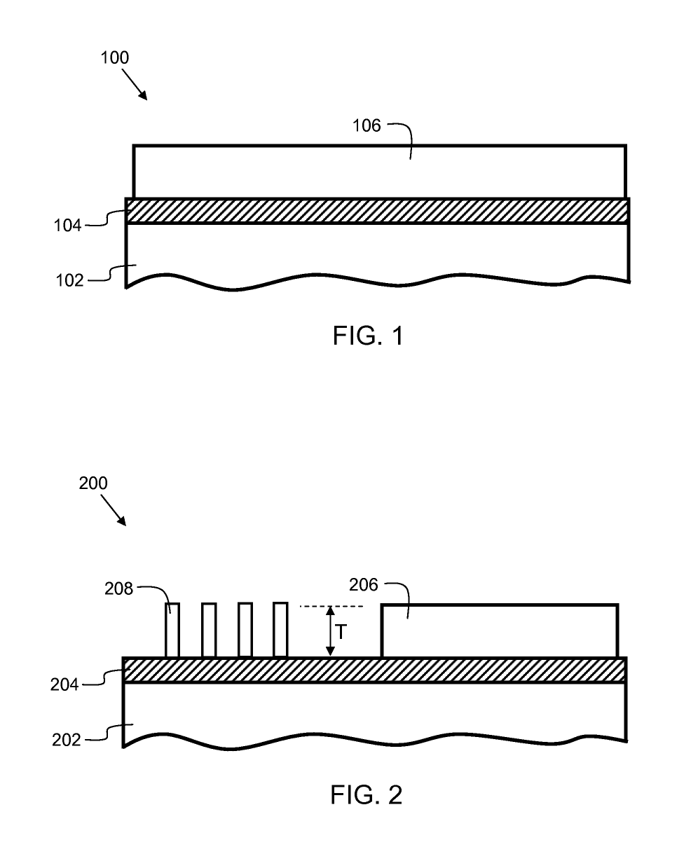

FIG. 1 shows a semiconductor structure 100 at a starting point for a method in accordance with an embodiment of the present invention. A bulk semiconductor substrate 102, which may comprise silicon, serves as the base of structure 100. An insulator layer 104 is disposed over the bulk semiconductor substrate 102. The insulator layer 104 may be a buried oxide (BOX) layer. In some embodiments, the insulator layer may have a thickness ranging from about 20 nanometers to about 80 nanometers. A silicon-on-insulator (SOI) region 106 is formed on the insulator layer 104.

FIG. 2 shows a semiconductor structure 200 after subsequent processing steps of forming multiple fins 208 from the SOI region 106. The fins 208 may be formed using industry-standard techniques of lithography and etching. A smaller portion of the SOI region 206 remains. The fins 208 are used to form a finFET device, and the SOI region 206 is used to form an adjacent diode. The fins 208 have a height T that is approximately the same height as the SOI region 206. In some embodiments, the height T ranges from about 20 nanometers to about 150 nanometers.

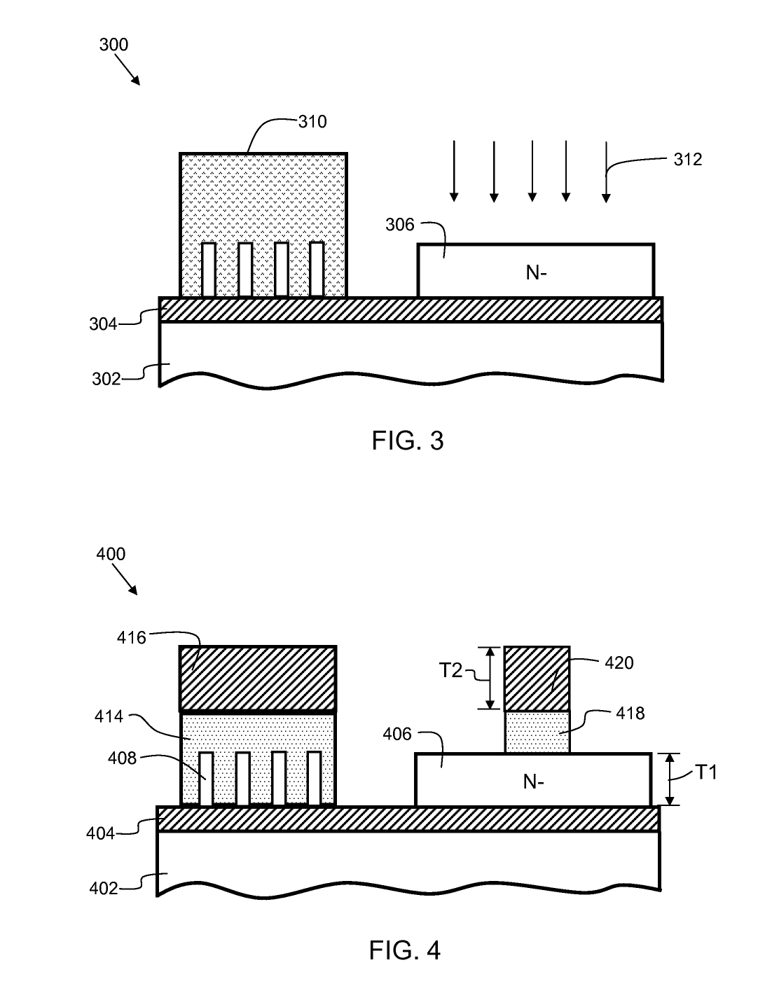

FIG. 3 shows a semiconductor structure 300 after subsequent processing steps of depositing a resist region 310 and performing a well implant, indicated by arrows 312. In some embodiments, the well implant includes adding N type dopants to form a N well. In some embodiments, the dopant comprises . The implant may be performed at an energy ranging from about 5 KeV to about 15 KeV. The resultant dopant concentration of region 306 may range from about 1E17 atoms per cubic centimeter to about 5E18 atoms per cubic centimeter, making region 306 lightly N doped (N−). The implanting may be followed by a well anneal. The well anneal may be performed at a temperature in the range of about 900 degrees Celsius to about 1100 degrees Celsius for a time ranging from about 3 seconds to about 60 seconds. In one embodiment, the well anneal is performed at a temperature of 1000 degrees Celsius for a duration of 5 seconds. In other embodiments, the dopant comprises phosphorus, and the phosphorus implant may be performed at an energy ranging from about 9 KeV to about 30 KeV.

FIG. 4 shows a semiconductor structure 400 after subsequent processing steps. The resist region 310 (of FIG. 3) is removed. Polysilicon is deposited and patterned using industry-standard methods, resulting in polysilicon region 414, which is deposited over the fins 408 and serves as a finFET gate, and polysilicon region 418, which is deposited on the SOI region 406 and serves as part of a diode. A gate dielectric layer (not shown) may be disposed between polysilicon region 414 and fins 408. An oxide hardmask is blanket deposited prior to the patterning of regions 414 and 418, and oxide regions 416 and 420 remain after patterning. In some embodiments, SOI region 406 may have a thickness T1 ranging from about 25 nanometers to about 40 nanometers. Oxide region 420 has a thickness T2 which is greater than thickness T1. In some embodiments, the oxide region 420 has a thickness ranging from about 45 nanometers to about 60 nanometers.

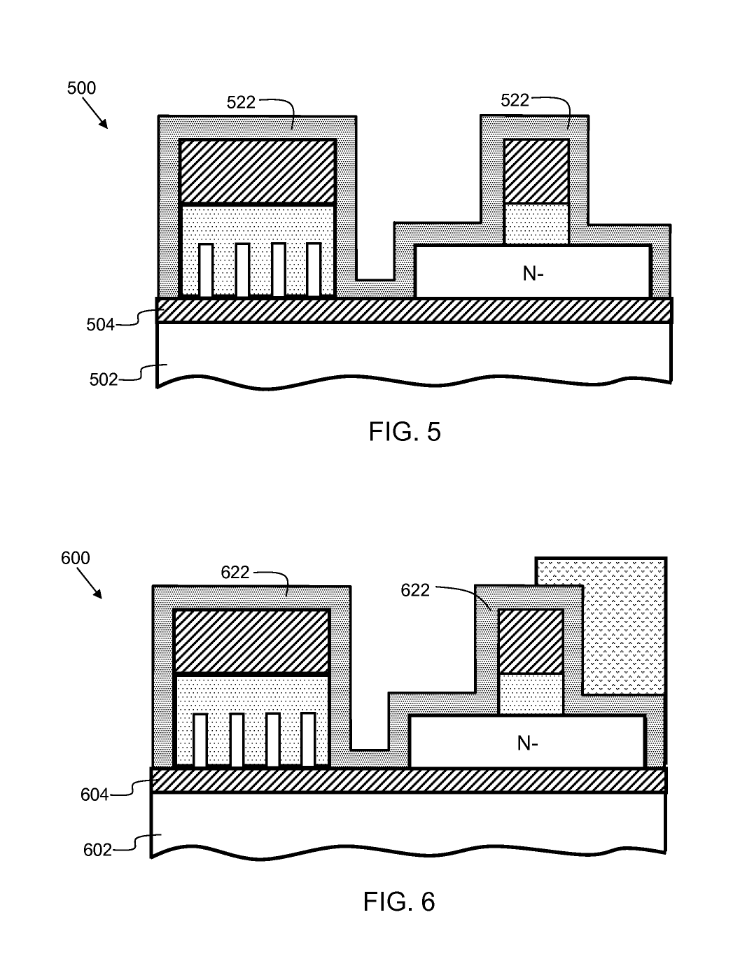

FIG. 5 shows a semiconductor structure 500 after a subsequent processing step of depositing a nitride layer 522. This nitride layer is used to protect silicon surfaces during an upcoming epitaxial process. In some embodiments, the nitride layer may have a thickness ranging from about 10 nanometers to about 30 nanometers.

FIG. 6 shows a semiconductor structure 600 after a subsequent processing step of depositing another resist region 624. Resist region 624 serves to protect the portion of the nitride layer 622 below it during subsequent processing.

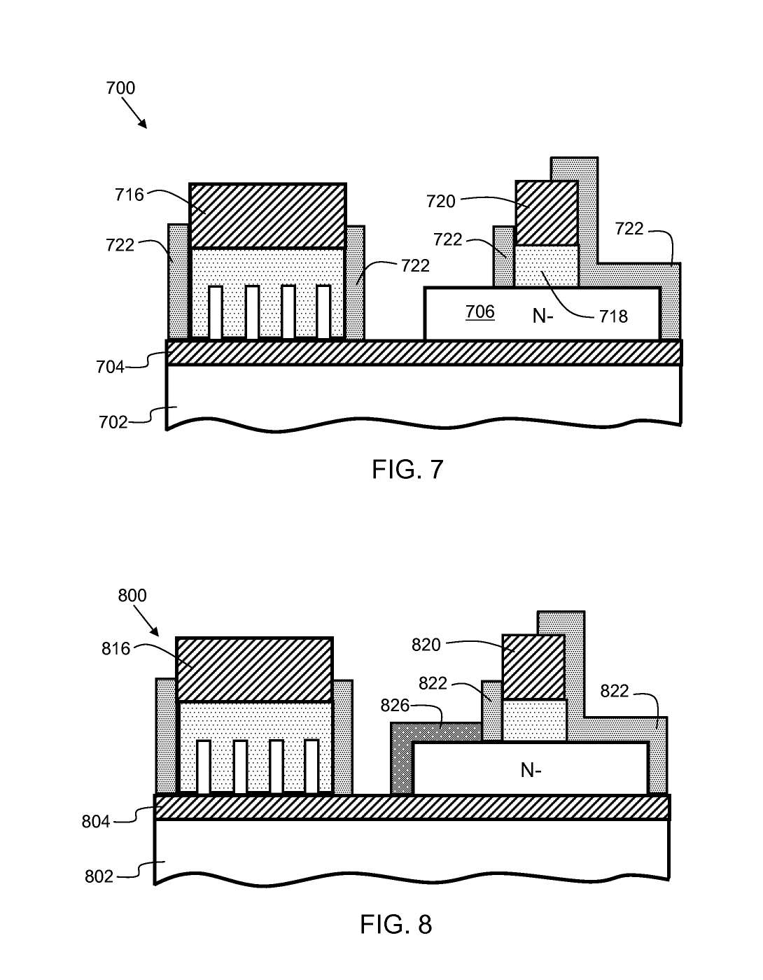

FIG. 7 shows a semiconductor structure 700 after a subsequent processing step of removing a portion of the nitride layer (compare 722 with 622 of FIG. 6). The remaining portions of the nitride layer are indicated as 722. The nitride layer is opened, exposing oxide regions 716 and 720, and a portion of SOI region 706. The exposed portion of SOI region 706 is needed so that an in-situ doped epitaxial layer can be grown on it in a downstream processing step. In some embodiments, the nitride layer 722 is opened using a reactive ion etch (RIE) process. Since oxide region 720 is thicker than SOI region 706 (see T1 and T2 of FIG. 4), a directional etch process, such as a RIE process completely removes the nitride on the left side of region 706, whereas the nitride region 722 remains on the left of oxide region 720, and still provides protection for polysilicon region 718 during an upcoming epitaxial process.

FIG. 8 shows a semiconductor structure 800 after a subsequent processing step of forming an in-situ doped P+ epitaxial silicon layer 826. The epitaxial silicon layer 826 only grows on exposed silicon, and does not grow on the oxide or nitride materials. In some embodiments, the P+ epitaxial layer is in-situ doped with boron, at a concentration ranging from about 1E20 atoms per cubic centimeter to about 1E21 atoms per cubic centimeter. In other embodiments, phosphorus may be used as the in-situ dopant.

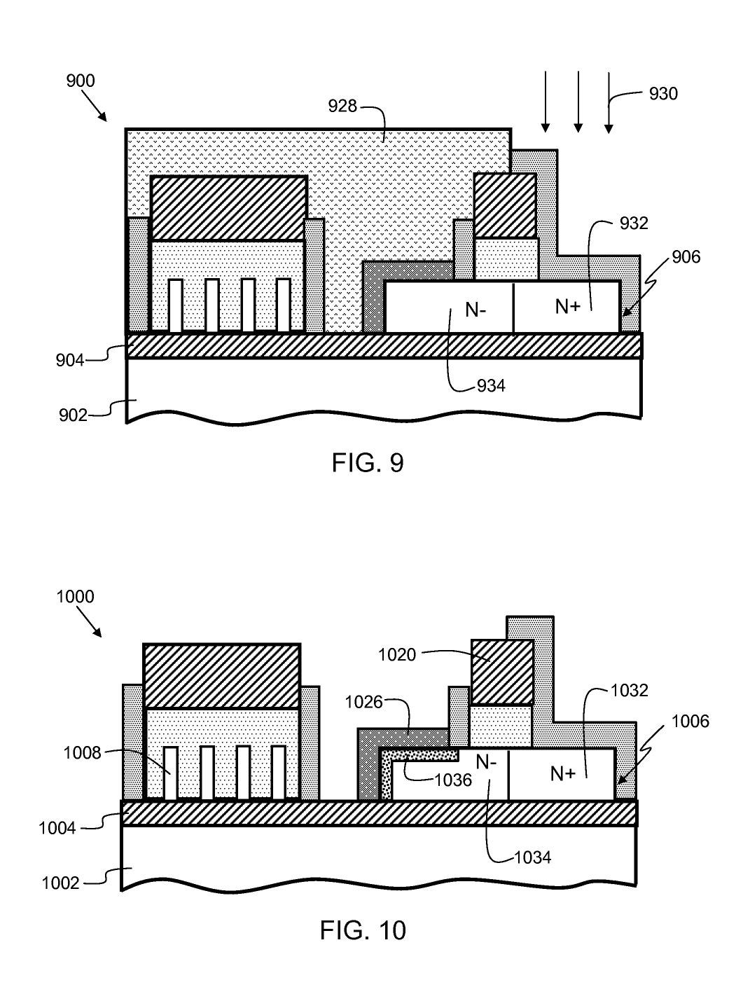

FIG. 9 shows a semiconductor structure 900 after subsequent processing steps. Another resist region 928 is formed using industry-standard deposition, lithographic, and patterning techniques. An N+ implant is performed (indicated by arrows 930), which forms an N+ region 932 within SOI region 906. The N+ region 932 will have a contact formed on it in a subsequent processing step. The N+ region may serve to lower contact resistance. In some embodiments, the N+ implant may implant arsenic dopants into region 932. The N+ region 932 is “heavily doped” with at least an order of magnitude higher dopant concentration than the “lightly doped” N− region, and may have a dopant concentration ranging from about 1E20 atoms per cubic centimeter to about 1E21 atoms per cubic centimeter. The portion of SOI region 906 directly underneath resist region 928, indicated as region 934, is shielded from the implant 930, and remains lightly N doped (N−).

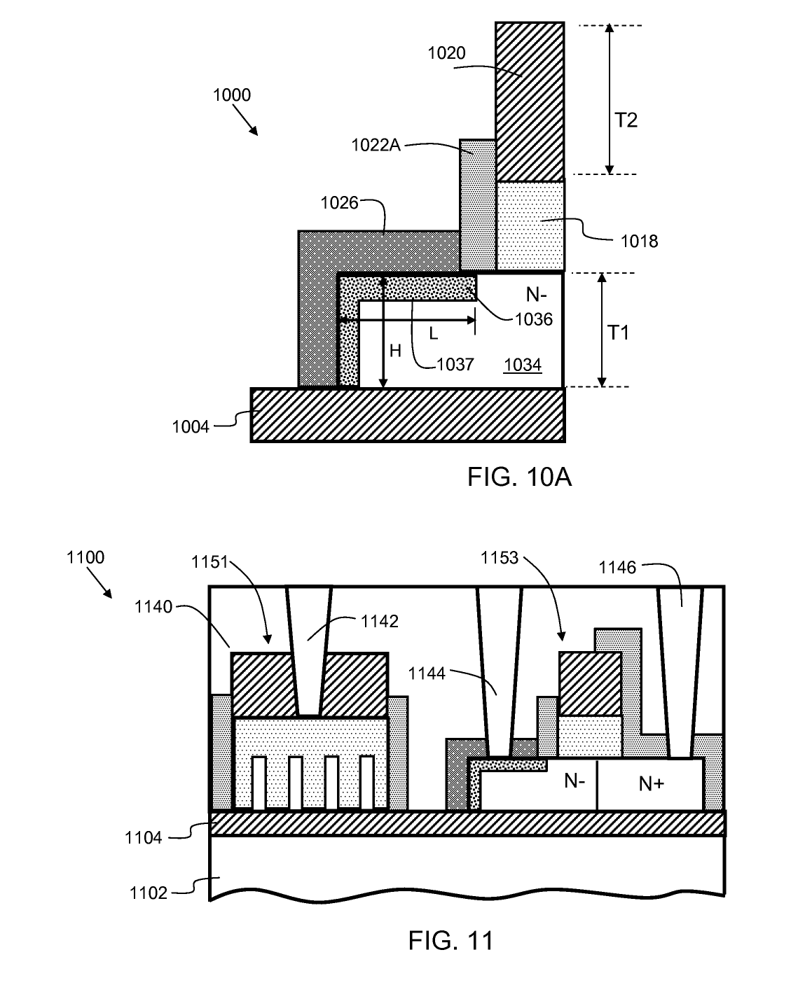

FIG. 10 shows a semiconductor structure 1000 after subsequent processing steps. The resist region (928 of FIG. 9) is removed. An activation anneal is performed which activates and diffuses dopants in P+ epitaxial region 1026 to form P− region 1036 within SOI region 1006. P+ region 1026 is in contact with P− region 1036 on its top and side. Hence, P+ region 1026 is above and alongside P− region 1036. In one embodiment, the activation anneal is performed at a temperature ranging from about 900 degrees Celsius to about 1100 degrees Celsius for a time ranging from about 3 seconds to about 60 seconds.

FIG. 10A shows details of the semiconductor structure of FIG. 10. As shown in FIG. 10A, P− region 1036 is an L-shaped region having a height H and a length L, which forms junction 1037 with N− region 1034. Thus, embodiments of the present invention provide an H component to the surface area of the junction between the N− region 1034 and the P+ region 1036. The height H is approximately the same height as the height of the N− region 1034. In some embodiments, L is about 45 nanometers and H is about 30 nanometers. In some embodiments, H is the same height as the N− region 1034, and L>H. Hence, the junction area is (H+L)*W, where W is the width of the diode (W is the dimension coming “out of the page” as shown in FIG. 10). In contrast, a traditional diode has a junction area of L*W. Hence for a “unit” device width of 1, the area of a traditional diode is 45 square nanometers and the area of the diode shown in FIG. 10 is (30+45)=75 square nanometers. Hence, the diode of semiconductor structure 1000 behaves as a traditional diode with a SOI height (see T of FIG. 2) of about 75 nanometers. However, it can be desirable to maintain the same height T1 for both the fins and the SOI region to streamline the fabrication process. Therefore, embodiments of the present invention provide the benefit of increasing the effective height of the SOI region 1006, while the physical height of the SOI region, including the N+ region 1032, is about the same height as the fins 1008. With the effective height of the SOI region increasing, the diode becomes more resilient to ESD events. In one embodiment, the SOI region has a physical height T1 of 35 nanometers and an effective height of 75 nanometers, due to the L shaped P+ region 1036. Oxide region 1020 has a height T2 which is larger than T1. In some embodiments, T2 ranges from about 45 nanometers to about 60 nanometers. The taller height of the oxide region 1020 as compared with the SOI region 1006 facilitates a directional etch resulting in nitride portion 1022A disposed above the SOI region 1006 and in direct physical contact with polysilicon region 1018. Nitride region 1022A completely covers one side of polysilicon region 1018, providing protection during the process of forming epitaxial silicon layer 1026.

In some embodiments, P+ region 1036 may have a dopant concentration ranging from about 1E20 atoms per cubic centimeter to about 1E21 atoms per cubic centimeter. In some embodiments, L-shaped P+ region 1036 may have a length ranging from about 40 nanometers to about 60 nanometers. In some embodiments, L-shaped P+ region 1036 may have a height ranging from about 20 nanometers to about 40 nanometers.

FIG. 11 shows a semiconductor structure 1100 after a subsequent processing step of adding electrical contacts. An interlevel dielectric layer 1140 is deposited over the semiconductor structure as part of the semiconductor fabrication process. Contacts are then formed in the interlevel dielectric layer 1140 to connect the circuitry to other circuits within the integrated circuit (IC) to which this circuit belongs. Contact 1142 is a gate contact for the finFET 1151. Contact 1146 is a first contact for diode 1153. Contact 1144 is a second contact for diode 1153. The contacts (1142, 1144, 1146) may be comprised of tungsten, copper, or other suitable conductor.

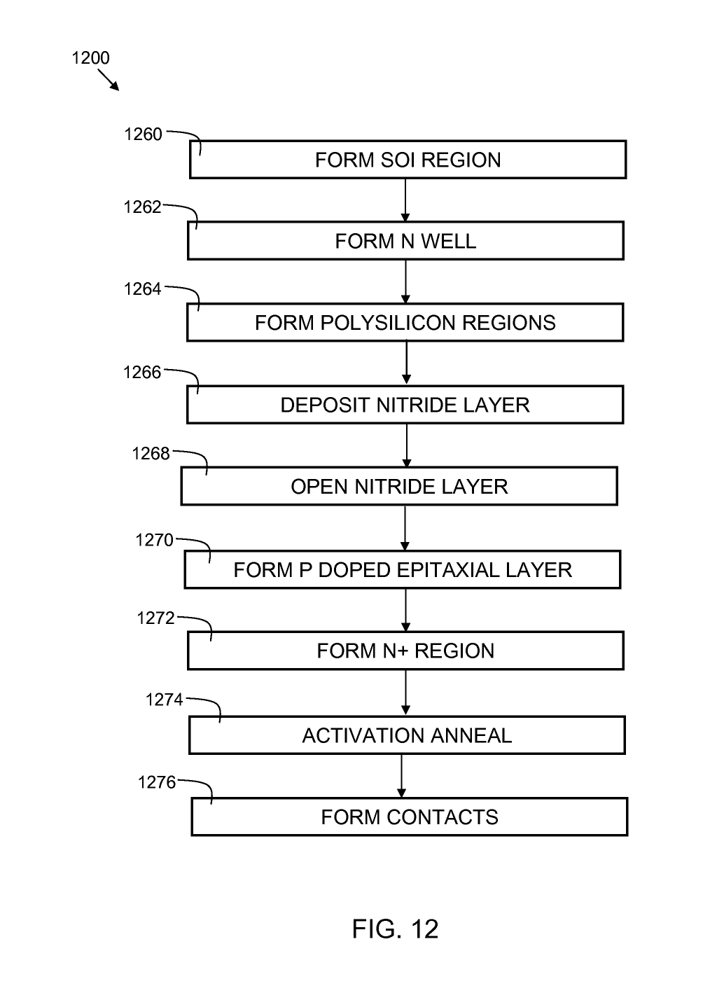

FIG. 12 is a flowchart 1200 indicating process steps for an embodiment of the present invention. In process step 1260, a SOI region is formed (see 206 of FIG. 2). In process step 1262, an N well is formed (see 306 of FIG. 3). In process step 1264, polysilicon regions are formed (see 414 and 418 of FIG. 4). In process step 1266, a nitride layer is deposited (see 522 of FIG. 5). In process step 1268, the nitride layer is opened (see 722 of FIG. 7). In process step 1270, an epitaxial silicon layer is formed, which is P+ doped in-situ (see 826 of FIG. 8). In process step 1272, an N+ region is formed (see 932 of FIG. 9). In process step 1274, an activation anneal is performed, which forms an L-shaped junction (see 1036 of FIG. 10). In process step 1276, electrical contacts are formed (see 1142, 1144, and 1146 of FIG. 11).

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A semiconductor diode comprising,
an N− region;
an L-shaped P− region formed within the N− region, wherein the L-shaped P− region forms an L-shaped junction with the N− region; and
a P+ region disposed above and alongside the P− region.

2. The diode of claim 1, wherein the P+ region is an in-situ doped epitaxial region.

3. The diode of claim 2, wherein the P+ region comprises a plurality of boron dopants.

4. The diode of claim 2, further comprising a polysilicon region disposed on the N− region.

5. The diode of claim 4, further comprising a nitride region disposed over the N− region, the nitride region in direct physical contact with, and completely covering one side of the polysilicon region.

6. The diode of claim 3, wherein the P+ region has a dopant concentration ranging from about 1E20 atoms per cubic centimeter to about 1E21 atoms per cubic centimeter.

7. The diode of claim 1, wherein the L-shaped junction has a height equal to the height of the N− region.

8. The diode of claim 7, wherein the L-shaped junction has a length that is longer than the height of the N− region.

9. A semiconductor structure, comprising:
a first silicon region;
an insulator region disposed over the first silicon region;
a diode, the diode comprising:
a second silicon region disposed over the insulator region;
an N+ region formed in the second silicon region;
an N− region formed in the second silicon region and disposed adjacent to the N+ region;
an L-shaped P− region formed within the N− region, wherein the L-shaped P− region forms an L-shaped junction with the N− region;
a P+ region disposed above and alongside the P− region; and
a finFET adjacent to the diode.

10. The semiconductor structure of claim 9, wherein the finFET comprises a plurality of fins having a fin height equal to the height of the N+ region.

11. The semiconductor structure of claim 9, further comprising:
a first contact disposed on the N+ region; and
a second contact disposed on the P+ region.

12. The semiconductor structure of claim 11, further comprising a third contact on a gate region of the finFET.

13. A method of forming a diode, comprising:
forming a silicon-on-insulator region;
forming a polysilicon region on the silicon-on-insulator region;
depositing a nitride layer over the silicon-on-insulator region;
forming an N+ region in the silicon-on-insulator region;
removing a portion of the nitride layer to form an exposed portion of the silicon-on-insulator region;
forming an in-situ P-doped epitaxial layer on the exposed portion of the silicon-on-insulator region;
performing an activation anneal; and
forming a first contact over the N+ region and a second contact over the in-situ P-doped epitaxial layer.

14. The method of claim 13, further comprising forming an N well on the silicon-on-insulator region.

15. The method of claim 13, wherein forming an N+ region comprises forming an N+ region having a dopant concentration ranging from about 1E20 atoms per cubic centimeter to about 1E21 atoms per cubic centimeter.

16. The method of claim 13, wherein depositing a nitride layer comprises depositing a nitride layer having a thickness ranging from about 10 nanometers to about 30 nanometers.

17. The method of claim 13, wherein forming an in-situ P-doped epitaxial layer on the exposed portion of the silicon-on-insulator region comprises adding a plurality of boron dopants.

18. The method of claim 13, wherein forming an in-situ P-doped epitaxial layer on the exposed portion of the silicon-on-insulator region comprises adding a plurality of phosphorus dopants.

19. The method of claim 17, wherein forming an in-situ P-doped epitaxial layer comprises forming an epitaxial layer having a dopant concentration ranging from about 1E17 atoms per cubic centimeter to about 1E18 atoms per cubic centimeter.

20. The method of claim 13, wherein performing an activation anneal comprises performing an activation anneal at a temperature ranging from about 900 degrees Celsius to about 1100 degrees Celsius for a time ranging from about 3 seconds to about 60 seconds.
